(19) United States
(12) Patent Application Publication
(10) Pub. No.: US 2025/0301573 A1
(43) Pub. Date: Sep. 25, 2025

(54) CONTACT ARRANGEMENT HAVING A WELDED FLEXIBLE CIRCUIT BOARD

(71) Applicant: Robert Bosch GmbH, Stuttgart (DE)

(72) Inventors: Philipp Gaertner, Filderstadt (DE); Andreas Markus Uyttendaele, Stuttgart (DE); Lukas Alter, Stuttgart (DE)

(21) Appl. No.: 18/861,313

(22) PCT Filed: May 2, 2023
(86) PCT No.: PCT/EP2023/061544

§ 371 Date: Oct. 29, 2024

(30) Foreign Application Priority Data
May 2, 2022 (DE) 10 2022 204 292.1

(51) Int. Cl. H05K 1/18; H05K 1/02

(52) U.S. Cl. CPC H05K 1/18; H05K 1/0277; H05K 2201/1028

(57) ABSTRACT

A contact arrangement. The contact arrangement has at least one electrically conductive substrate, in particular a circuit carrier. The contact arrangement also has a flexible circuit board having at least one reversibly bendable, electrically insulating film and at least one or only one electrically conductive layer. The electrically conductive layer is electrically conductively connected to the substrate. The contact arrangement has an electrically conductive connecting element, which is arranged on the electrically conductive layer of the flexible circuit board so that the connecting element and the substrate enclose the flexible circuit board between them. The connecting element is welded to the electrically conductive layer of the flexible circuit board and to the substrate such that a welded connection extends from the connecting element through the electrically conductive layer of the flexible circuit board, in particular transversely to a flat extent of the flexible circuit board, into the substrate.

### FIELD

The present invention relates to a contact arrangement. The contact arrangement has at least one electrically conductive substrate, in particular a circuit carrier. The contact arrangement also has an in particular flexible circuit board wherein the flexible circuit board has at least one, in particular reversibly bendable, electrically insulating film and at least one or only one electrically conductive layer. The electrically conductive layer of the flexible circuit board is electrically conductively connected to the substrate, in particular while lying on the substrate.

### BACKGROUND INFORMATION

German Patent No. DE 10 2019 128 634 B3 describes a bonded self-supporting conductor connection between two bonding points, at each of which an integral bond of the self-supporting conductor with a bonding surface is created in a bonding step and between which the conductor runs in a bonding loop.

### SUMMARY

According to the present invention, a contact arrangement has an electrically conductive connecting element, which is arranged on the electrically conductive layer of the flexible circuit board such that the connecting element and the substrate enclose the flexible circuit board between them. The connecting element is welded to the electrically conductive layer of the flexible circuit board and to the substrate such that a welded connection extends from the connecting element through the electrically conductive layer of the flexible circuit board, in particular transversely to a flat extent of the flexible circuit board, into the substrate. Advantageously, a low-resistance and in particular solder-free electrical connection can thus be formed between the flexible circuit board and the substrate, in particular a circuit carrier, for example a DCB substrate (DCB=direct copper bonded) or an AMB substrate (AMB=active metal brazed).

It was found that the connecting element can reinforce the electrically conductive layer of the flexible circuit board such that it is advantageously not possible for the electrically conductive layer of the flexible circuit board to burn away during laser welding.

According to an example embodiment of the present invention, the flexible circuit board is preferably designed to be bent transversely to its flat extent without breaking. Preferably, the flexible circuit board has a polyimide layer, a polyamide layer, a PET layer (PET=polyethylene terephthalate), a PVB layer (polyvinyl butyral), a PVF layer (PVF=polyvinyl fluoride) or an EVA layer (EVA=ethylene vinyl acetate) as an electrically insulating layer or electrically insulating film. The electrically conductive layer of the flexible circuit board is preferably a copper layer or a metal layer made of a copper alloy.

Preferably, the connecting element is designed to at least partially absorb heat generated during welding. Advantageously, the connecting element can thus form both a heat store for excess process heat during welding and a material reserve, which can advantageously reinforce the electrically conductive layer in the region of the welded connection when welding the flexible circuit board to the substrate.

In a preferred embodiment of the contact arrangement of the present invention, the welded connection is a laser welded connection. Advantageously, a circuit carrier, in particular a ceramic circuit carrier, can thus be welded to the flexible circuit board from only one side.

In another example embodiment of the present invention, the substrate is formed by a lead frame, in particular a piece of sheet metal. In this embodiment, the welded connection is, for example, a resistance spot welded connection. Advantageously, during resistance welding, additional welding material for forming an electrical contact bridge between the flexible circuit board and the substrate can thus be formed by means of the connecting element.

In a preferred embodiment of the present invention, the connecting element has a surface extent which, in particular in a plane of the flexible circuit board, extends radially outward beyond the spatial extent of the welded connection, wherein the connecting element covers the flexible circuit board outside the welded connection. Advantageously, a mechanical reinforcement and a form-fitting holding function, in particular a type of collar, can thus be formed around the welded connection, wherein the collar can mechanically retain and stabilize the flexible circuit board in the region of the welded connection.

In a preferred embodiment of the contact arrangement of the present invention, the welded connection is formed by means of a weld bead extending flatly in the substrate plane, in particular extending longitudinally. The weld bead extends in the connecting element, the flexible circuit board and the substrate. Preferably, the weld bead is designed to completely penetrate through the connecting element, the flexible circuit board, in particular the at least one electrically conductive layer of the flexible circuit board. Advantageously, an electrically conductive integral bond can thus be formed between the joining partners.

In a preferred embodiment of the present invention, the welded connection is only partially formed along a thickness extent of the substrate, in particular of an electrically conductive layer, in particular rewiring layer, of the substrate. Advantageously, the electrically conductive layer of the substrate, in particular a ceramic substrate, thus cannot be mechanically deformed by heat input.

In a preferred embodiment of the contact arrangement of the present invention, the substrate has at least one electrically insulating ceramic layer and at least one electrically conductive layer. The substrate is, for example, a DCB substrate (DCB=direct copper bonded), an AMB substrate (AMB=active metal brazed), an IMS substrate (IMS=insulated metal substrate), an LTCC substrate (LTCC=low-temperature cofired ceramic) or an HTCC substrate (HTCC=high-temperature cofired ceramic).

Advantageously, a flexible circuit board can thus be connected to an in particular ceramic substrate without solder. The flexible circuit board is also advantageously protected by means of the connecting element against unintentional tearing, insofar as the connecting element forms a collar which projects laterally beyond the welded connection and which is designed to hold the flexible circuit board on and/or press it onto the substrate.

In a preferred embodiment of the present invention, the connecting element has a greater thickness extent than the electrically conductive layer of the flexible circuit board. Advantageously, additional material as well as a mechanical collar for fixing the flexible circuit board on the substrate can thus be formed during welding.

In a preferred embodiment of the present invention, the welded connection, in particular the weld bead, has the same width extent as the thickness extent of the connecting element. For example, the weld bead has a width extent between 100 and 300 micrometers, preferably between 180 micrometers and 220 micrometers, or 200 micrometers. An exemplary thickness of the connecting element is between 150 and 250 micrometers, preferably between 180 and 220 micrometers. Advantageously, a stable and electrically highly conductive welded connection can thus be formed.

In a preferred embodiment of the contact arrangement of the present invention, the connecting element is a bonding band longitudinal portion, further preferably made of copper or a copper alloy. Advantageously, the connecting element can thus be applied to the flexible circuit board in a cost-effective manner by means of a bonding device. Further advantageously, the connecting element can thus be unrolled from a bonding band supply, in particular a bonding band roll, and the longitudinal portion can be welded to the circuit carrier and cut off.

In a preferred embodiment of the present invention, the connecting element is a metal plate. Advantageously, the connecting element can thus be placed on the circuit carrier, in particular the flexible circuit board, in the region of the electrical connection point by means of vacuum assembly, in particular by means of an automatic placement machine. The metal plate is designed, for example, to be self-adhesive and has an adhesive on a side facing the flexible circuit board, at least or only on a surface subregion that is not to be welded.

For example, the connecting element, in particular the metal plate, for example a copper plate, can be placed on the circuit carrier by an automatic placement machine, which is designed to retain the metal plate by means of a vacuum force, to deposit the metal plate on the circuit carrier, and to press it onto the circuit carrier, in particular the flexible circuit board, and, during the pressing process, to send a laser beam onto the metal plate in the region of a pressing element, and to weld the metal plate to the flexible circuit board and the substrate. Advantageously, the welding connection process can thus be integrated into an automated assembly process during the assembly of a circuit carrier.

Advantageously, an integrally bonded three-layer composite can thus be produced from the aforementioned joining partners.

The present invention also relates to a contact system comprising at least one contact arrangement according to the type described above. The contact arrangement has at least one further substrate, wherein the substrate and the further substrate are electrically conductively connected to each other by means of the flexible circuit board. Preferably, the electrical connection points of the flexible circuit board with the substrate are created by means of the connecting element, which is placed on the flexible circuit board, and the welded integral connection, which penetrates through the connecting element and the flexible circuit board and extends into the substrate. Advantageously, different substrates, in particular circuit carriers, can thus be electrically connected to one another in a cost-effective manner by means of a flexible circuit board.

In a preferred embodiment of the present invention, the flexible circuit board has a connector for electrically connecting the substrate. The connector can be connected to the flexible circuit board in addition to the further substrate mentioned above, or instead of the further substrate. Advantageously, an electrical connection of a substrate, in particular a ceramic circuit carrier, to a plug connection can thus be designed to be cost-effective, reliable and durable.

In a preferred embodiment of the present invention, the flexible circuit board can be formed on the circuit carrier as a further attached rewiring layer, on which electronic components, for example a sensor, can be arranged. Advantageously, the flexible circuit board can be welded to the circuit carrier without solder so that the layer composite comprising the circuit carrier and the flexible circuit board can be inserted into a soldering furnace for reflow soldering of electronic components on the layer composite without the layer composite produced without solder being able to dissolve again.

The present invention also relates to a method for integrally bonding a flexible circuit board to a substrate. In the method, a surface region of the flexible circuit board is electrically conductively connected and integrally bonded to a substrate.

According to an example embodiment of the present invention, preferably, a flatly extending connecting element is placed on the surface region of the flexible circuit board, and the three-layer arrangement thus produced, comprising the substrate, the flexible circuit board and the flatly extending connecting element, is welded by means of a laser beam to form a three-layer composite, in which the joining partners are preferably integrally bonded to one another while lying on top of one another.

According to an example embodiment of the present invention, preferably, the three-layer composite is welded by means of the laser beam from the side of the connecting element. Advantageously, this can create a durable, low-resistance electrical connection between the flexible circuit board and the substrate.

The present invention is explained in more detail below with reference to figures and further exemplary embodiments. Further advantageous embodiment variants result from a combination of the features disclosed herein.

### BRIEF DESCRIPTION OF THE DRAWINGS

FIG. 1 shows a welding device and a method for welding a flexible circuit board to a circuit carrier according to an example embodiment of the present invention, in which a connecting element formed by a bonding band longitudinal portion is arranged on the flexible circuit board, and the connecting element is welded together with the flexible circuit board and the circuit carrier by means of laser beams, and the bonding band longitudinal portion is cut off from the remaining bonding band after welding.

FIG. 2 shows an exemplary embodiment of a contact arrangement produced by means of the welding device and the method shown in FIG. 1, according to the present invention.

FIG. 3 shows a variant of the method shown in FIG. 1, in which a metal plate is placed on the flexible circuit board and welded to the flexible circuit board and the circuit carrier to form a three-layer connection, according to the present invention.

### DETAILED DESCRIPTION OF EXAMPLE EMBODIMENTS

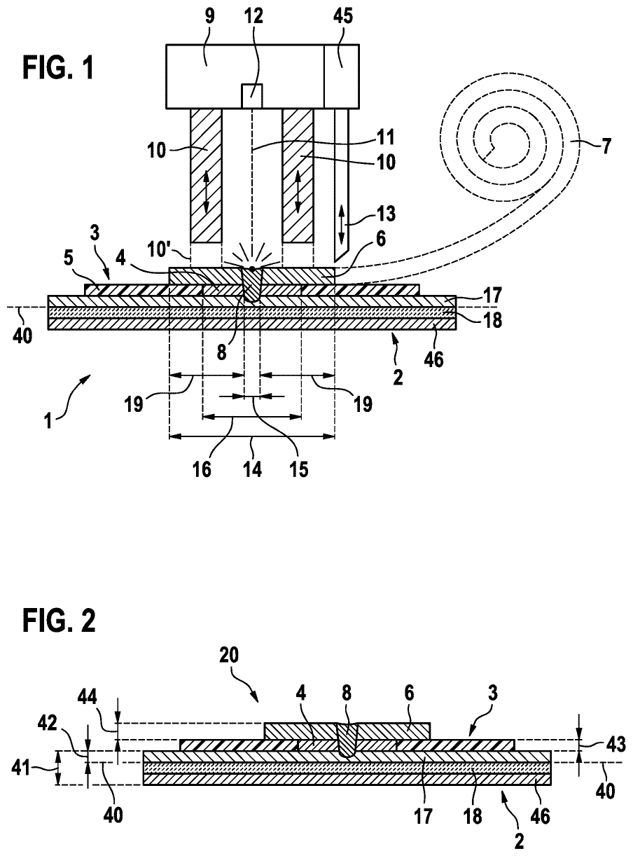

FIG. 1 shows, schematically, an exemplary embodiment of a method 1 for producing a connection arrangement by means of a welding device 9. The connection arrangement comprises a circuit carrier 2, a flexible circuit board 3, and an electrically conductive connecting element 6. In this exemplary embodiment, the connecting element 6 is formed by a bonding band longitudinal portion of a bonding band 7.

In the method, a welding device 9, which has a hold-down device 10 and a laser 12, which is designed to generate a laser beam 11, is placed on a three-layer arrangement comprising the circuit carrier 2, the flexible circuit board 3 and the connecting element 6 formed by the bonding band longitudinal portion. The hold-down device 10 is designed to press the connecting element 6 transversely to a flat extent 40 of the circuit carrier 2 and to press said circuit carrier against the flexible circuit board 3 and thus also against the substrate formed by the circuit carrier 2. The hold-down device 10 is shown in a holding position 10′ supported on the connecting element 6.

The flexible circuit board 3 has an electrically insulating film 5 and an electrically conductive layer 4, in particular a copper layer, extending in a plane of the flexible film. The laser beams 11 are designed to connect, in particular to weld, the bonding band longitudinal portion 6, the electrically conductive layer 4 and an electrically conductive rewiring layer 17 of the circuit carrier 2 to one another in a form-fitting manner.

For this purpose, a region, struck by the laser beams 11, of the connecting element 6 formed by the bonding band longitudinal portion can be vaporized and/or melted by the laser beams 11, wherein adjacent metal regions in the region of the vaporization zone can melt into the vaporization zone, and a melting pot of liquefied metal produced in the region of the laser beams 11 can thus form. The zone of the liquefied metal extends through the connecting element 6, in particular the bonding band portion, and further through the electrically conductive layer 4 and further into the electrically conductive layer 17, in particular the rewiring layer of the circuit carrier 2. After solidification, the melting zone thus formed in the depth of the stacked layers, formed by the bonding band portion 6, the electrically conductive layer 4 and the circuit carrier 2, can produce a form-fitting welded connection between the electrically conductive layer of the flexible circuit board 3 and the circuit carrier 2, in particular the electrically conductive layer 17.

The welded connection 8 formed in the flat extent 40 of the circuit carrier 2 along a width extent 15 thus has a smaller width extent than a width extent 14 of the connecting element 6, which in this exemplary embodiment has been severed from the bonding band 7 by means of a cutting blade 13 moved by a cutting device 45, after the welded connection 8 has been created. In this example, the cutting device 45 is part of the welding device and is arranged and designed to move the cutting blade 13 back and forth and to sever a bonding band longitudinal portion, extending along the width extent 14, of the bonding band 7 from the bonding band 7 and thus to produce the separated connecting element 6.

In this way, a collar 19 can be formed around the welded connection 8, which collar can cover the flexible circuit board 3, in particular the electrically conductive layer 4 surrounding the welded connection 8, and in this exemplary embodiment also a region of the electrically insulating layer 5, in particular in the manner of a nail head or a rivet head, and can thus clamp it between the circuit carrier 2 and the connecting element 6.

In this exemplary embodiment, the width extent 14 of the connecting element 6 is larger than a width extent 16 of the electrically conductive layer 4, which is formed in the flexible circuit board 3. With the width extent 14 of the connecting element 6, a surface region which corresponds to the width extent 14 and extends radially outward beyond the welded connection 8 is also covered on the flexible circuit board 3 by the connecting element 6. In this way, a type of collar is formed, which can press the flexible circuit board, welded to the circuit carrier, onto the circuit carrier and retain it there.

The flexible circuit board 3 has a polyimide film, a polyamide film, a Mylar layer, in particular a polyethylene terephthalate layer, or an elastomer layer as the electrically insulating material 5.

The flexible circuit board is designed to be so flexible that it can be bent back and forth transversely to a flat extent of the flexible circuit board without breaking.

FIG. 2 shows, schematically, a connection arrangement 20 produced by means of the method 1 shown in FIG. 1. The connection arrangement 20 comprises the substrate 2, a ceramic circuit carrier in this exemplary embodiment, comprising the electrically insulating ceramic layer 18 shown in FIG. 1, and an electrically conductive rewiring layer 17, in particular a copper layer. In addition to the rewiring layer 17, the circuit carrier 2 has an electrically conductive rear layer 46, which together with the electrically conductive rewiring layer 17 encloses the electrically insulating layer 18 between them. The connection arrangement 20 also comprises the flexible circuit board 3 and the connecting element 6.

In the connection arrangement 20, the three layers of the three-layer composite, formed by the circuit carrier 2, the flexible circuit board 3, and the connecting element 6, lie on top of one another, wherein the integrally bonded welded connection 8 integrally bonds the three joining partners, namely, the connecting element 6, the flexible circuit board 3, in particular the electrically conductive layer 4 of the flexible circuit board 3, and the circuit carrier 2, in particular the electrically conductive layer 17 of the circuit carrier 2, and at least partially or completely penetrates through them transversely to a flat extent 40 of the circuit carrier 2. In this exemplary embodiment, the welded connection 8 penetrates with a smaller depth extent through the circuit carrier 2 than the thickness extent 41 thereof, and also with a smaller depth extent than the thickness extent 42 of the electrically conductive layer 17, in particular the rewiring layer.

A thickness extent 44 of the connecting element 6 is larger than a thickness extent 43 of the electrically conductive layer 4 of the flexible circuit board 3 or of the flexible circuit board itself. The thickness extent of the electrically conductive layer 4 can correspond to a thickness extent of the electrically insulating layer 5. This allows the flexible circuit board 3 to have an isotropic thickness.

In another embodiment, the connection arrangement 20 can have a punched piece of sheet metal, also called a lead frame, as a substrate instead of the ceramic circuit carrier 2.

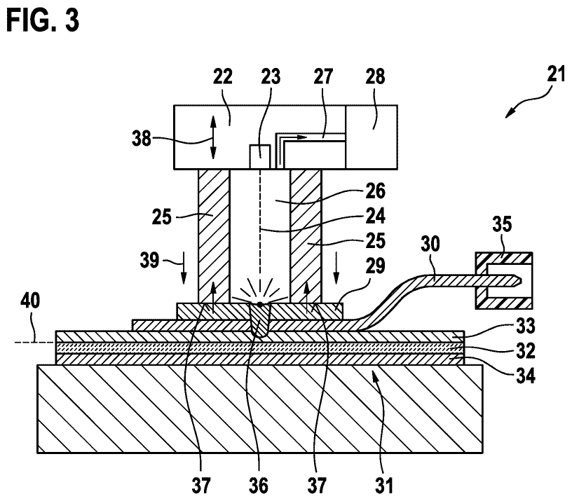

FIG. 3 shows, schematically, an exemplary embodiment of a connecting method 21 for integrally bonding and electrically conductively connecting a circuit carrier 31 to a flexible circuit board 30.

In the joining method shown in FIG. 3, a laser welding device 22 has a laser 23 for generating a laser beam 24 and a hold-down device formed by a tube 25, wherein the laser 23 is arranged and designed to send the laser beam 24 through a cylindrical cavity 26, which is enclosed by the tube 25, along the longitudinal extent of the cavity 26.

The tube 25 has an end face 37, which is designed to be placed on a connecting element 29, in this exemplary embodiment formed by a metal plate, a lead frame, or a piece of sheet metal, for transporting the connecting element to the welding location on the circuit carrier 31, and to suck all the air out of the cavity 26, bordering the connecting element 29, by means of a vacuum pump 28 so that the connecting element 29 can be sucked against the end face 37 of the tube 25.

A suction channel 27 connects the cavity 26 to the vacuum pump 28. The laser welding device 22 can be part of a manufacturing device and, as indicated by arrow 38, can be moved up or down at least transversely to a flat extent 40 of the circuit carrier 31. In this way, after sucking the connecting element 29 formed by the metal plate, the laser welding device 22 can placed the connecting element 29 on the flexible circuit board 30, placed on the circuit carrier 31, in the direction 39 of the circuit carrier 31 and can be pressed onto said circuit board by the laser welding device 22.

The laser welding device 22 can be designed to press the tube 25, in particular the end face 37 of the tube 25, against the connecting element 29 so that the flexible circuit board 30 is firmly clamped between the connecting element 29 and the circuit carrier 31 in the region of the end face 37.

By means of the laser beam 24, the welded connection 36 can then be created, which fuses the connecting element 29, the flexible circuit board 30 and the electrically conductive layer 33 of the circuit carrier 31 together and can thus integrally bond them to one another.

After the welded connection 36 has cooled and solidified, the manufacturing device 22 can switch off the vacuum pump 28 so that the connecting element 29 is released after the tube 25 is lifted off the connecting element 29.

In this exemplary embodiment, the circuit carrier 31 comprises an electrically insulating layer 32, in particular a ceramic layer, which is enclosed, in particular in the manner of a sandwich, between the electrically conductive layer 33 and a further electrically conductive rear layer 34.

In this embodiment, the flexible circuit board 30 has, by way of example, a connector 35 so that an electrical or electronic circuit arrangement formed on the circuit carrier 31 can be electrically connected by means of the connector 35 to further electronic components on the outside. Instead of the connector, the flexible circuit board 30 can be plugged, welded or soldered to a further circuit carrier.

1-13. (canceled)

14. A contact arrangement, comprising:
at least one electrically conductive substrate;
a flexible circuit board, wherein the flexible circuit board has at least one reversibly bendable electrically insulating film and at least one or only one electrically conductive layer, and wherein the electrically conductive layer of the flexible circuit board is electrically conductively connected to the substrate while lying on the substrate;
wherein the contact arrangement has an electrically conductive connecting element, which is arranged on the electrically conductive layer of the flexible circuit board so that the connecting element and the substrate enclose the flexible circuit board between them, wherein the connecting element is welded to the electrically conductive layer of the flexible circuit board and to the substrate such that a welded connection extends from the connecting element through the electrically conductive layer of the flexible circuit board transversely to a flat extent of the flexible circuit board, into the substrate.

15. The contact arrangement according to claim 14, wherein the welded connection is a laser welded connection.

16. The contact arrangement according to claim 14, wherein the connecting element extends radially outward from the welded connection and covers the flexible circuit board.

17. The contact arrangement according to claim 14, wherein the welded connection is formed by a weld bead, which extends flatly in a plane of the substrate and extends longitudinally, and extends in the connecting element, the flexible circuit board and in the substrate, wherein the weld bead completely penetrates through the connecting element and at least the electrically conductive layer of the flexible circuit board.

18. The contact arrangement according to claim 14, wherein the welded connection is only partially formed along a thickness extent of the substrate.

19. The contact arrangement according to claim 14, wherein the substrate has at least one electrically insulating ceramic layer and at least one electrically conductive layer.

20. The contact arrangement according to claim 14, wherein the connecting element has a greater thickness extent than a thickness extent of the electrically conductive layer of the flexible circuit board.

21. The contact arrangement according to claim 14, wherein the weld bead has a same width extent as a thickness extent of the connecting element.

22. The contact arrangement according to claim 14, wherein the connecting element is formed by a bonding band longitudinal portion.

23. The contact arrangement according to claim 14, wherein the connecting element is a metal plate.

24. A contact system, comprising:
at least one contact arrangement including,
at least one electrically conductive substrate,
a flexible circuit board, wherein the flexible circuit board has at least one reversibly bendable electrically insulating film and at least one or only one electrically conductive layer, and wherein the electrically conductive layer of the flexible circuit board is electrically conductively connected to the substrate while lying on the substrate,
wherein the contact arrangement has an electrically conductive connecting element, which is arranged on the electrically conductive layer of the flexible circuit board so that the connecting element and the substrate enclose the flexible circuit board between them, wherein the connecting element is welded to the electrically conductive layer of the flexible circuit board and to the substrate such that a welded connection extends from the connecting element through the electrically conductive layer of the flexible circuit board transversely to a flat extent of the flexible circuit board, into the substrate;
wherein the contact arrangement further includes at least one further substrate, and the substrate and the further substrate are electrically conductively connected to each other by the flexible circuit board;
wherein electrical connection points of the flexible circuit board with the substrate are created by the connecting element, which is placed on the flexible circuit board, and the welded connection, which penetrates through the connecting element and the flexible circuit board and extends into the substrate.

25. A contact system, comprising
at least one contact arrangement including:
at least one electrically conductive substrate,
a flexible circuit board, wherein the flexible circuit board has at least one reversibly bendable electrically insulating film and at least one or only one electrically conductive layer, and wherein the electrically conductive layer of the flexible circuit board is electrically conductively connected to the substrate while lying on the substrate,
wherein the contact arrangement has an electrically conductive connecting element, which is arranged on the electrically conductive layer of the flexible circuit board so that the connecting element and the substrate enclose the flexible circuit board between them, wherein the connecting element is welded to the electrically conductive layer of the flexible circuit board and to the substrate such that a welded connection extends from the connecting element through the electrically conductive layer of the flexible circuit board transversely to a flat extent of the flexible circuit board, into the substrate;
wherein the flexible circuit board has a connector for electrically connecting the substrate.

26. A method for integrally bonding a flexible circuit board to a substrate, in which a surface region of the flexible circuit board is electrically conductively connected and integrally bonded to a substrate, the method comprising:
placing a flatly extending connecting element on the surface region of the flexible circuit board; and
welding a three-layer arrangement thus produced using a laser beam to form a three-layer composite.
